(19) United States
(12) Patent Application Publication
(10) Pub. No.: US 2006/0071318 A1
(43) Pub. Date: Apr. 6, 2006

(54) Methods for manufacturing semiconductor device, semiconductor device and metal mold

(76) Inventor: Tomoyoshi Yamamura, Sakata (JP)

Correspondence Address: HARNESS, DICKEY & PIERCE, P.L.C., P.O. BOX 828, BLOOMFIELD HILLS, MI, 48303, US

(21) Appl. No.: 11/230,266

(22) Filed: Sep. 19, 2005

(30) Foreign Application Priority Data
Oct. 5, 2004 (JP) 2004-292208

(51) Int. Cl. H01L 23/02

(52) U.S. Cl. 257/686

(57) ABSTRACT

A method for manufacturing a semiconductor device including: fixing each of a plurality of semiconductor substrates onto a surface of a wiring substrate in which a perforation is formed in advance; covering the surface of the wiring substrate with a metal mold having a protrusion on an inner surface along the perforation; wholly sealing the plurality of semiconductor substrates with a sealing resin by introducing the sealing resin into the metal mold while forming a thin region in the sealing resin along the perforation; and dividing the wiring substrate into a plurality of chips by splitting the wiring substrate and the sealing resin along the perforation in the wiring substrate and the thin region in the sealing resin.

### TECHNICAL FIELD

The present invention relates to methods for manufacturing a semiconductor device, as well as semiconductor devices and a metal mold. Especially, the invention relates to methods for manufacturing a semiconductor device, as well as semiconductor devices and a metal mold, that can divide a wiring substrate and a sealing resin into chips without using a blade.

### RELATED ART

FIG. 11 is a perspective view for describing a conventional method for manufacturing a semiconductor device. A semiconductor device manufactured by the conventional method has a configuration wherein a semiconductor substrate 101 is fixed on a wiring substrate 102.

First of all, the semiconductor substrate 101 and the wiring substrate 102 are prepared. On the wiring substrate 102, wiring is formed in advance. On the semiconductor substrate 101, a semiconductor element (not illustrated) such as a transistor, etc.; a wiring layer (not illustrated); and a pad (not illustrated) are formed in advance. The semiconductor element is coupled to the pad through the wiring layer.

Next, a plurality of the semiconductor substrates 101 are fixed onto the top surface of the wiring substrate 102. Then, the pad of the semiconductor substrate 101 is coupled to the wiring substrate 102 using a wire 101a. After that, the surface of the wiring substrate 102 is sealed with a sealing resin 103. By this method, the semiconductor substrate 101 and the wire 101a are protected. Further, a soldering ball (not illustrated) for external coupling is formed on the back surface of the wiring substrate 102. Then, the wiring substrate 102 and the sealing resin 103 are cut into a plurality of chips of the individual semiconductor substrates 101 using a blade 104.

However, the conventional method wherein a wiring substrate and a sealing resin are divided using a blade involves a problem that shavings may remain on the cut surface. Remaining shavings may cause another problem in the post-process. Therefore, there has been a need of removing shavings after cutting a substrate, which has required a certain amount of labor.

Further, if a blade is worn down, more shavings tend to be generated on the cut surface. Therefore, blades need to be changed frequently to some extent, which has increased the manufacturing cost of a semiconductor device.

### SUMMARY

An advantage of the invention is to provide methods for manufacturing a semiconductor device, as well as semiconductor devices and a metal mold, that can divide a wiring substrate and a sealing resin into chips without using a blade.

According to a first aspect of the invention, a method for manufacturing a semiconductor device includes: fixing each of a plurality of semiconductor substrates onto the surface of a wiring substrate in which a perforation is formed in advance; covering the surface of the wiring substrate with a metal mold having a protrusion on the inner surface along the perforation; wholly sealing the plurality of semiconductor substrates with a sealing resin by introducing the sealing resin into the metal mold while forming a thin region in the sealing resin along the perforation; and dividing the wiring substrate into a plurality of chips by splitting the wiring substrate and the sealing resin along the perforation in the wiring substrate and the thin region in the sealing resin.

With the above method for manufacturing a semiconductor device, due to the perforation formed in the wiring substrate and the thin region formed in the sealing resin, the wiring substrate and the sealing resin can be divided into a plurality of chips by splitting the wiring substrate along the perforation and the thin region. Therefore, shavings hardly remain on the end faces of the wiring substrate and the sealing resin after division. Further, since there is no need of using a blade, the manufacturing cost of a semiconductor device can be reduced.

According to a second aspect of the invention, another method for manufacturing a semiconductor device includes: fixing each of a plurality of first semiconductor substrates onto the surface of a wiring substrate in which a groove is formed in advance; covering the surface of the wiring substrate with a metal mold having a protrusion on the inner surface along the groove; wholly sealing the plurality of first semiconductor substrates with a sealing resin by introducing the sealing resin into the metal mold while forming a thin region in the sealing resin along the groove; and dividing the wiring substrate into a plurality of chips by splitting the wiring substrate and the sealing resin along the groove in the wiring substrate and the thin region in the sealing resin.

According to a third aspect of the invention, yet another method for manufacturing a semiconductor device includes: fixing each of a plurality of first semiconductor substrates onto the surface of a wiring substrate in which a perforated groove is formed in advance; covering the surface of the wiring substrate with a metal mold having a protrusion on the inner surface along the perforated groove; wholly sealing the plurality of first semiconductor substrates with a sealing resin by introducing the sealing resin into the metal mold while forming a thin region in the sealing resin along the perforated groove; and dividing the wiring substrate into a plurality of chips by splitting the wiring substrate and the sealing resin along the perforated groove in the wiring substrate and the thin region in the sealing resin.

With the above two methods for manufacturing a semiconductor device, the wiring substrate and the sealing resin can be divided into a plurality of chips by splitting the wiring substrate and the sealing resin along the groove and the thin region. Therefore, shavings hardly remain on the end faces of the wiring substrate and the sealing resin after division. Further, since there is no need of using a blade, the manufacturing cost of a semiconductor device can be reduced.

It is preferable that the wiring substrate is divided into a plurality of chips by, for example, bending the wiring substrate along the groove in the wiring substrate and the thin region in the sealing resin.

It is also preferable to further include coupling the first semiconductor substrates to the wiring substrate using a wire between the step for fixing the plurality of first semiconductor substrates onto the wiring substrate and the step for mounting the metal mold on the surface of the wiring substrate.

It is also preferable to further include fixing a second semiconductor substrate on each of the plurality of first semiconductor substrates and coupling the second semiconductor substrate to the wiring substrate using a wire between the step for fixing the plurality of first semiconductor substrates onto the wiring substrate and the step for mounting the metal mold on the surface of the wiring substrate.

It is also preferable to further include fixing a plurality of second semiconductor substrates onto each of the plurality of first semiconductor substrates, with the plurality of second semiconductor substrates laminated with each other, and coupling at least one of the plurality of laminated second semiconductor substrates to the wiring substrate using a wire between the step for fixing the plurality of first semiconductor substrates onto the wiring substrate and the step for mounting the metal mold on the surface of the wiring substrate.

According to a fourth aspect of the invention, yet another method for manufacturing a semiconductor device includes: fixing each of a plurality of semiconductor substrates onto the surface of a wiring substrate in which a perforation is formed in advance; wholly sealing the plurality of first semiconductor substrates with a sealing resin while forming a thin region in the sealing resin along the perforation; and dividing the wiring substrate into a plurality of chips by splitting the wiring substrate and the sealing resin along the perforation in the wiring substrate and the thin region in the sealing resin.

In each of the above methods for manufacturing a semiconductor device, it is preferable that the perforation or the groove in the wiring substrate is formed by means of laser irradiation or etching. It is also preferable that the thickness of the thin region in the sealing resin is ⅓ or less of the thickness of the sealing resin around the first semiconductor substrates.

According to a fifth aspect of the invention, a semiconductor device includes: a semiconductor substrate; a wiring substrate coupled to the semiconductor substrate, which is fixed on the wiring substrate; and a sealing resin for sealing the semiconductor substrate on the wiring substrate. In the above semiconductor device, the sealing resin is thinner on at least one side of the wiring substrate than other regions and the side of the wiring substrate is formed by splitting the wiring substrate along a perforation formed in the wiring substrate.

According to a sixth aspect of the invention, another semiconductor device includes: a semiconductor substrate; a wiring substrate coupled to the semiconductor substrate, which is fixed on the wiring substrate; and a sealing resin for sealing the semiconductor substrate on the wiring substrate. In the above semiconductor device, the sealing resin is thinner on at least one side of the wiring substrate than other regions; and the side of the wiring substrate is formed by splitting the wiring substrate along a groove formed in the wiring substrate.

According to a seventh aspect of the invention, yet another semiconductor device includes: a semiconductor substrate; a wiring substrate coupled to the semiconductor substrate, which is fixed on the wiring substrate; and a sealing resin for sealing the semiconductor substrate on the wiring substrate. In the above semiconductor device, the sealing resin is thinner on at least one side of the wiring substrate than other regions and the side of the wiring substrate is formed by splitting the wiring substrate along a perforated groove formed in the wiring substrate.

According to an eighth aspect of the invention, a metal mold includes a protrusion on the inner surface along a perforation or a groove formed in the surface of a wiring substrate, onto which a semiconductor substrate is fixed. The above metal mold is used to seal the semiconductor substrate with resin and to cover the surface of the wiring substrate.

### BRIEF DESCRIPTION OF THE DRAWINGS

The invention will be described with reference to the accompanying drawings, wherein like numbers refer to like elements, and wherein:

FIG. 1 is a side view for describing the configuration of a semiconductor device formed in a first embodiment of the invention;

FIG. 2 is a flow chart showing a method for manufacturing the semiconductor device in FIG. 1;

FIG. 3A is a perspective view of a wiring substrate 2 in a step S2 in FIG. 2;

FIG. 3B is a schematic perspective view for describing a step S4 in FIG. 2;

FIG. 4 is a schematic cross section for describing steps S6 and S8 in FIG. 2;

FIG. 5 is a schematic cross section for describing a step S12 in FIG. 2;

FIG. 6 is a perspective view for describing a method for manufacturing a semiconductor device according to a second embodiment of the invention;

FIG. 7 is a perspective view for describing a method for manufacturing a semiconductor device according to a third embodiment of the invention;

FIG. 8 is a side view of a semiconductor device according to a fourth embodiment of the invention;

FIG. 9 is a side view of a semiconductor device according to a fifth embodiment of the invention;

FIG. 10 is a side view of a semiconductor device according to a sixth embodiment of the invention; and

FIG. 11 is a perspective view for describing a conventional method for manufacturing a semiconductor device.

### DESCRIPTION OF THE EMBODIMENTS

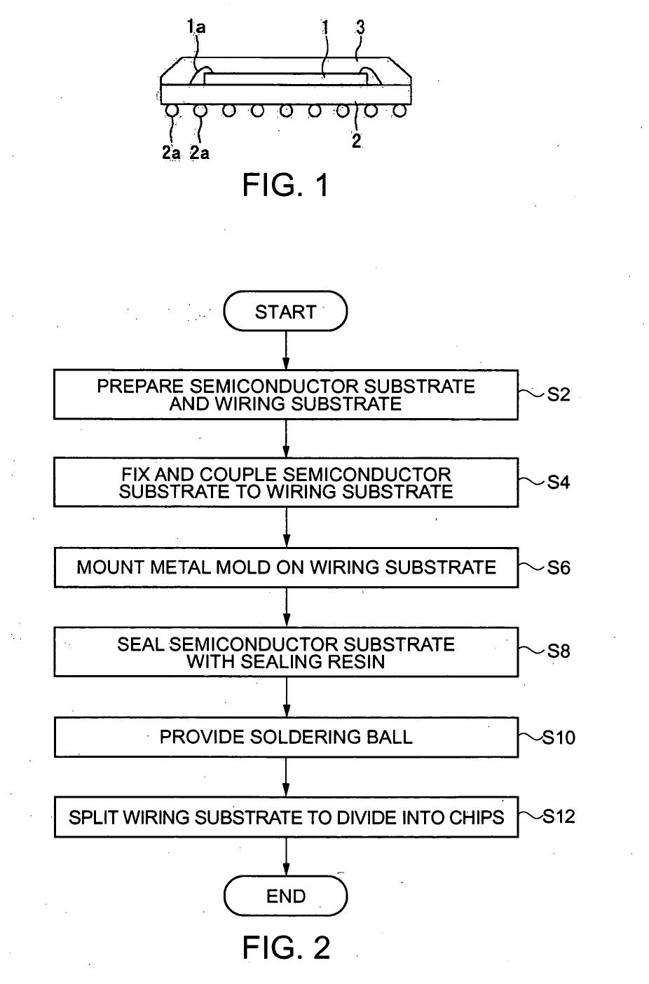

Embodiments of the invention will now be described with reference to the accompanying drawings. FIG. 1 is a side view for describing the configuration of a semiconductor device formed in a first embodiment of the invention. The semiconductor device has a configuration of PFBGA (plastic fine pitch ball grid array). More specifically, a semiconductor substrate 1 is fixed onto the surface of a wiring substrate 2, and the semiconductor substrate 1 and the wiring substrate 2 are coupled to each other through a wire 1a. The semiconductor substrate 1 and the wire 1a are sealed with a sealing resin 3, which is formed on the wiring substrate 2, for protection purposes.

On the semiconductor substrate 1, a plurality of transistors (not illustrated) are formed. Further on the transistors, a plurality of wiring layers are formed. The transistors are coupled, through the plurality of wiring layers, to an Al alloy pads (not illustrated) exposed on the surface of the wiring layers. To the Al alloy pad, the wire 1a is coupled.

The wiring substrate 2 is configured of insulative resin layers (not illustrated) and copper wiring pattern layers (not illustrated) that are laminated alternately and has a thickness of, for example, 125 μm or more but 420 μm or less. At the top surface of the wiring substrate 2 comes a wiring pattern layer.

In addition, the wiring substrate 2 can also be configured of a single resin layer and a single wiring layer.

On the back surface of the wiring substrate 2, a plurality of soldering balls 2a are formed to serve as external input/output terminals. The soldering balls 2a are coupled to the wiring layer through a coupling hole (not illustrated) provided on the resin layer of the wiring substrate 2.

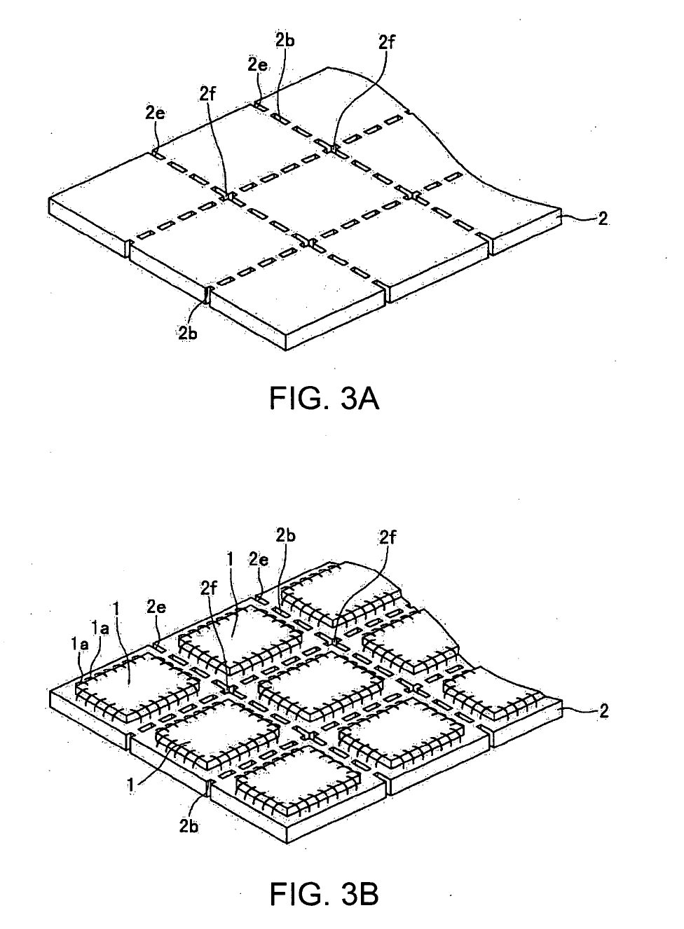

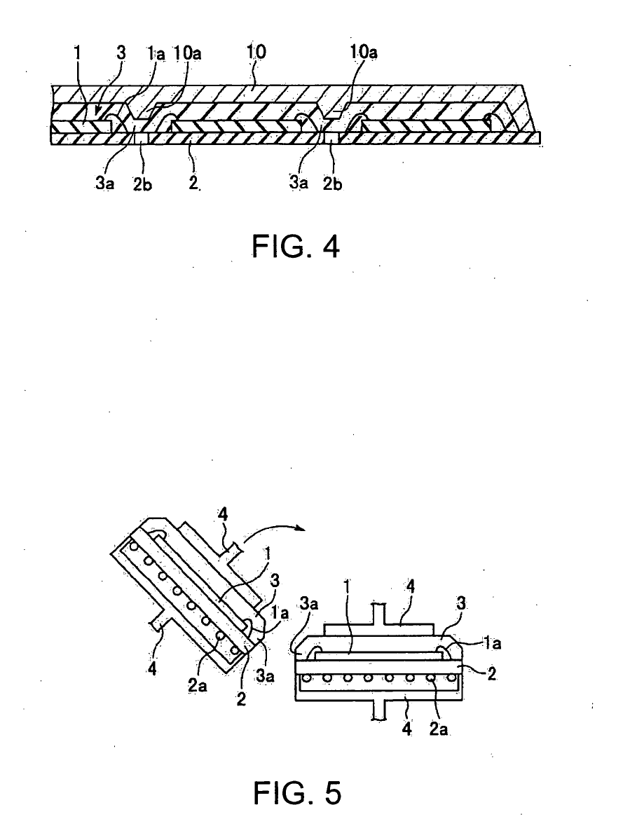

FIG. 2 is a flow chart showing the method for manufacturing the semiconductor device in FIG. 1. FIG. 3A is a perspective view of the wiring substrate 2 in a step S2 in FIG. 2, and FIG. 3B is a schematic perspective view for describing a step S4 in FIG. 2. FIG. 4 is a schematic cross section for describing steps S6 and S8 in FIG. 2. FIG. 5 is a schematic cross section for describing a step S12 in FIG. 2.

First of all, the semiconductor substrate 1 and the wiring substrate 2 are prepared (S2 in FIG. 2). In this step, transistors, wiring layers, and an Al alloy pad are formed on the semiconductor substrate 1. In addition, on the wiring substrate 2, a resin layer and a wiring pattern layer are formed but not the soldering ball 2a.

Further, as shown in FIG. 3A, the plurality of wiring substrates 2 are formed, being coupled to one another with a perforation 2b in between. The perforation 2b is formed by, for example, irradiating a laser beam onto the wiring substrate 2.

In addition, the perforation 2b can be formed simultaneously with the wiring substrate 2 by repeating the following steps. First of all, a resin layer is formed and then a copper thin film is formed on the resin layer. Next, a mask, such as a photoresist pattern, etc., is formed on the copper thin film and then the thin film is etched using the mask. By this method, the copper thin film is patterned to form a wiring pattern layer. Then, after the mask on the wiring pattern is removed, a new mask, such as a photoresist pattern, etc., is formed and the resin layer is etched using the new mask. By this method, the perforation 2b is formed in the resin layer. After that, the mask is removed.

It is preferable that the perforation 2b is formed so as to overlap with the edges of the wiring substrate 2 (for example, the part indicated by a reference numeral 2e) or other perforations 2b (for example, the part indicated by a reference numeral 2f). By this method, it becomes easy to split the wiring substrate 2 linearly at the edges and the intersections of the perforations 2b in the division step, which will be described later.

Next, using a bonding agent, the semiconductor substrate 1 is fixed at a specified position on the wiring substrate 2. Then, using the wire 1a, the Al alloy pad of the semiconductor substrate 1 and the wiring pattern of the wiring substrate 2 are coupled (S4 in FIG. 2 and FIG. 3B).

After that, a metal mold 10 is mounted on the wiring substrate 2 to cover the top surface of the wiring substrate 2 with the metal mold 10 (S6 in FIG. 2 and FIG. 4). Then, the sealing resin 3 is injected through an injection port (not illustrated) of the metal mold 10. By this method, the plurality of semiconductor substrates 1 and wires 1a provided on the top surface of the wiring substrate 2 are wholly sealed with the sealing resin 3 (S8 in FIG. 2 and FIG. 4).

In addition, as shown in FIG. 4, the metal mold 10 has a protrusion 10a on the inner surface along the perforation 2b. Therefore, a thin region 3a is formed in the sealing resin 3 along the perforation 2b. The preferable thickness of the thin region 3a is ⅓ or less of the thickness of the sealing resin 3 around the semiconductor substrates 1.

Then, the soldering balls 2a are provided on the back surface of the wiring substrate 2 (S10 in FIG. 2). Further, using a splitter 4, the wiring substrate 2 and the sealing resin 3 are bent along the perforation 2b and the thin region 3a. By this method, the wiring substrate 2 and the sealing resin 3 are split along the perforation 2b and the thin region 3a to be divided into chips of the individual semiconductor substrates 1 (S12 in FIG. 2 and FIG. 5). Therefore, the wiring substrate 2 after division is formed with at least one side being split along the perforation.

In addition, as shown in FIG. 5, it is preferable that the splitter 4 is configured so as to bend the wiring substrate 2 and the sealing resin 3 by supporting the bottom of the wiring substrate 2, avoiding the soldering balls 2a, while supporting the top surface of the sealing resin 3. By this method, the soldering balls 2a and the semiconductor substrate 1 can be prevented from being stressed when splitting the wiring substrate 2.

As described above, the semiconductor device according to the first embodiment is divided into chips by forming in advance the perforation 2b and the thin region 3a in each of the wiring substrate 2 and the sealing resin 3 and then splitting the wiring substrate 2 and the sealing resin 3 along the perforation 2b and the thin region 3a. Therefore, the wiring substrate 2 and the sealing resin 3 can be divided into chips without using a blade. This means that a step for removing shavings can be omitted because no shavings are generated on the divided section. Further, since there is no need of using a blade, the manufacturing cost of a semiconductor device can be reduced.

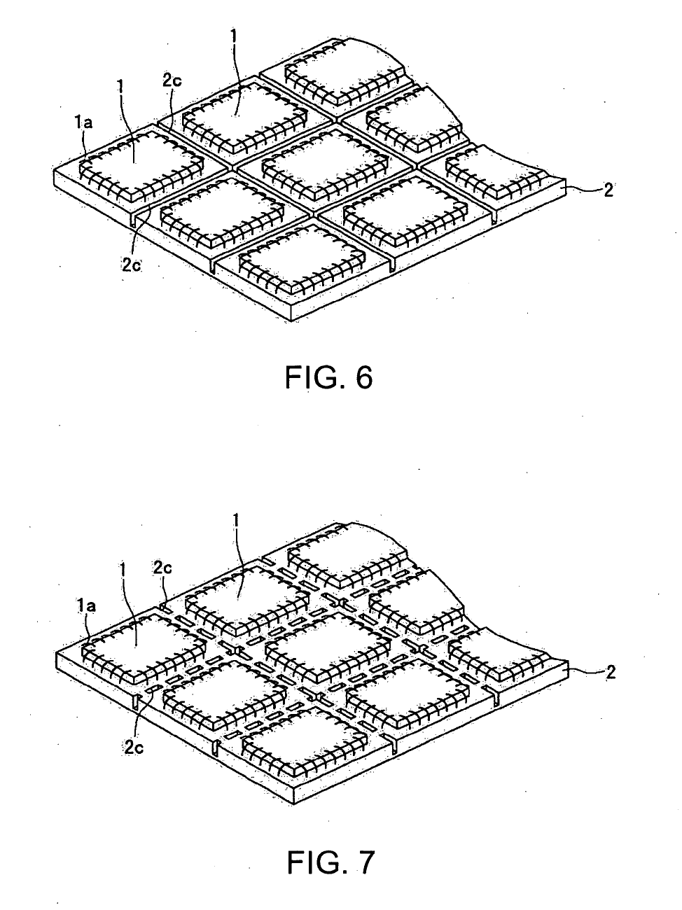

FIG. 6 is a perspective view for describing a method for manufacturing a semiconductor device according to a second embodiment of the invention. The second embodiment is the same as the method for manufacturing a semiconductor device according to the first embodiment except that a groove 2c is formed instead of the perforation 2b. Further, a semiconductor device formed in the second embodiment is formed with at least one side being split along the groove 2c. Also in the second embodiment, the same effect as in the first embodiment can be obtained.

FIG. 7 is a perspective view for describing a method for manufacturing a semiconductor device according to a third embodiment of the invention. The third embodiment is the same as the second embodiment except that the groove 2c is formed in a perforated shape. Further, a semiconductor device formed in the third embodiment is formed with at least one side being split along the perforated groove 2c. Also in the third embodiment, the same effect as in the first embodiment can be obtained.

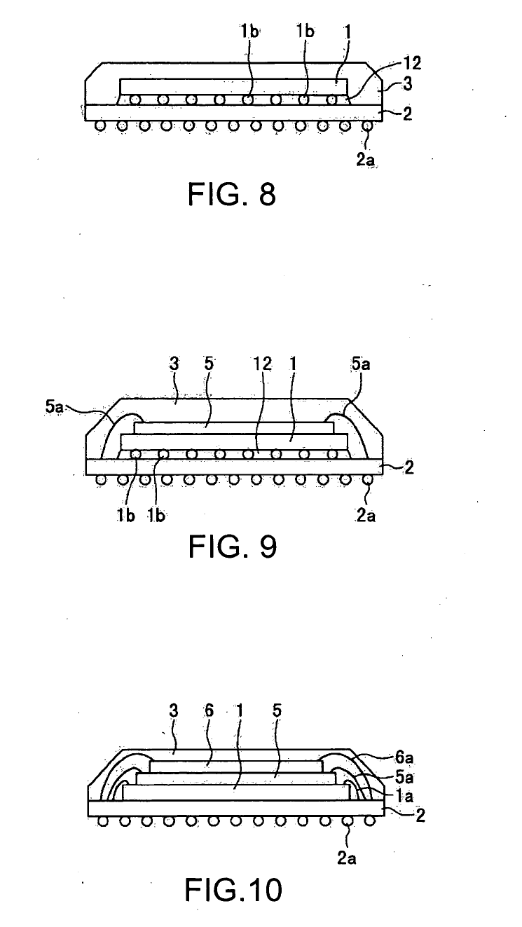

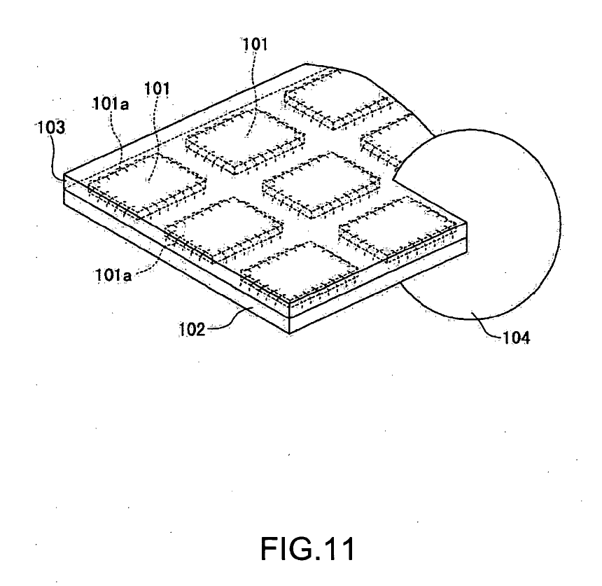

FIG. 8 is a side view of a semiconductor device according to a fourth embodiment of the invention. The fourth embodiment differs from the first embodiment on the point that the wiring pattern on the wiring substrate 2 is coupled to the Al alloy pad via a gold bump 1b that is formed on the Al alloy pad of the semiconductor substrate 1. The descriptions of the other configurations, which are the same as those of the first embodiment, are omitted by describing FIG. 8 using the same reference numerals.

The semiconductor device according to the fourth embodiment is formed as follows. First of all, the semiconductor substrate 1 and the wiring substrate 2 are prepared. Then, using a seal-type anisotropic conductive resin 12, the semiconductor substrate 1 is fixed at a specified position on the wiring substrate 2, with the gold bump 1b coupled to the wiring pattern on the wiring substrate 2 through the anisotropic conductive resin 12.

Next, the metal mold 10 shown in FIG. 4 is mounted on the wiring substrate 2 and the sealing resin 3 is injected into the metal mold 10. By this method, the plurality of semiconductor substrates 1 on the wiring substrate 2 are wholly sealed with the sealing resin 3. Then, the soldering balls 2a are provided on the back surface of the wiring substrate 2. Further, using the splitter 4, the wiring substrate 2 is bent along the perforation 2b. By this method, the wiring substrate 2 is split along the perforation 2b to be divided into chips of the individual semiconductor substrates 1.

Also in the fourth embodiment, the same effect as in the first embodiment can be obtained.

FIG. 9 is a side view of a semiconductor device according to a fifth embodiment of the invention. In the fifth embodiment, a semiconductor substrate 5 is fixed on the semiconductor substrate 1. The pad (not illustrated) provided on the semiconductor substrate 5 is coupled to the wiring pattern of the wiring substrate 2 via a wire 5a. The descriptions of the other configurations, which are the same as those of the fourth embodiment, are omitted by describing FIG. 9 using the same reference numerals.

The semiconductor device according to the fifth embodiment is formed as follows. First of all, the semiconductor substrate 1 and the wiring substrate 2 are prepared. Then, using the seal-type anisotropic conductive resin 12, each of the plurality of semiconductor substrates 1 is fixed at a specified position on the wiring substrate 2, with the gold bump 1b coupled to the wiring pattern on the wiring substrate 2 through the anisotropic conductive resin 12.

Next, the semiconductor substrate 5 is fixed on each of the semiconductor substrates 1. Then, the Al alloy pad of the semiconductor substrate 5 and the wiring pattern on the wiring substrate 2 are coupled to each other using the wire 5a. Further, the metal mold 10 shown in FIG. 4 is mounted on the wiring substrate 2 and the sealing resin 3 is injected into the metal mold 10. By this method, the plurality of semiconductor substrates 1 and 5 and the wires 5a on the wiring substrate 2 are wholly sealed with the sealing resin 3. Then, the soldering balls 2a are provided on the back surface of the wiring substrate 2. Further, using the splitter 4, the wiring substrate 2 is bent along the perforation 2b. By this method, the wiring substrate 2 is split along the perforation 2b to be divided into chips of the individual semiconductor substrates 1 and 5.

Also in the fifth embodiment, the same effect as in the first embodiment can be obtained.

FIG. 10 is a side view of a semiconductor device according to a sixth embodiment of the invention. The sixth embodiment is the same as the first embodiment except the points that the semiconductor substrate 5 and a semiconductor substrate 6 are laminated in the described order on the semiconductor substrate 1 and that the Al alloy pads of the semiconductor substrates 5 and 6 are coupled to the wiring pattern on the wiring substrate 2 via the wire 5a and a wire 6a. The descriptions of the same configurations as those of the first embodiment are omitted by describing FIG. 10 using the same reference numerals.

The semiconductor device according to the sixth embodiment is formed as follows. First of all, a plurality of the semiconductor substrates 1 and the wiring substrate 2 are prepared. Then, each of the plurality of semiconductor substrates 1 are fixed at a specified position on the wiring substrate 2. Next, the semiconductor substrates 5 and 6 are laminated and fixed in the described order on each of the semiconductor substrates 1. Further, using the wires 1a, 5a, and 6a, the Al alloy pads of the semiconductor substrates 1, 5, and 6 are coupled to the wiring pattern of the wiring substrate 2. The descriptions of the subsequent steps, which are the same as in the first embodiment, are omitted.

Also in the sixth embodiment, the same effect as in the first embodiment can be obtained.

In addition, the invention is not limited to the above embodiments and can be modified variously within the scope of the invention. For example, in the methods for manufacturing a semiconductor device according to the fourth to sixth embodiments, the groove 2c, which is described in the second or the third embodiment, can be provided on the wiring substrate 2 instead of the perforation 2b. Also by this method, the same effect as in the first embodiment can be obtained.

What is claimed is:

1. A method for manufacturing a semiconductor device, comprising:
fixing each of a plurality of semiconductor substrates onto a surface of a wiring substrate in which a perforation is formed in advance;
covering the surface of the wiring substrate with a metal mold having a protrusion on an inner surface along the perforation;
wholly sealing the plurality of semiconductor substrates with a sealing resin by introducing the sealing resin into the metal mold while forming a thin region in the sealing resin along the perforation; and
dividing the wiring substrate into a plurality of chips by splitting the wiring substrate and the sealing resin along the perforation in the wiring substrate and the thin region in the sealing resin.

2. A method for manufacturing a semiconductor device, comprising:
fixing each of a plurality of first semiconductor substrates onto a surface of a wiring substrate in which a groove is formed in advance;
covering the surface of the wiring substrate with a metal mold having a protrusion on an inner surface along the groove;
wholly sealing the plurality of first semiconductor substrates with a sealing resin by introducing the sealing resin into the metal mold while forming a thin region in the sealing resin along the groove; and
dividing the wiring substrate into a plurality of chips by splitting the wiring substrate and the sealing resin along the groove in the wiring substrate and the thin region in the sealing resin.

3. A method for manufacturing a semiconductor device, comprising:
fixing each of a plurality of first semiconductor substrates onto a surface of a wiring substrate in which a perforated groove is formed in advance;
covering the surface of the wiring substrate with a metal mold having a protrusion on an inner surface along the perforated groove;
wholly sealing the plurality of first semiconductor substrates with a sealing resin by introducing the sealing resin into the metal mold while forming a thin region in the sealing resin along the perforated groove; and
dividing the wiring substrate into a plurality of chips by splitting the wiring substrate and the sealing resin along the perforated groove in the wiring substrate and the thin region in the sealing resin.

4. The method for manufacturing a semiconductor device according to claim 1, wherein the step for dividing the wiring substrate into a plurality of chips includes splitting the wiring substrate by bending the wiring substrate along the perforation in the wiring substrate and the thin region in the sealing resin.

5. The method for manufacturing a semiconductor device according to claim 2, wherein the step for dividing the wiring substrate into a plurality of chips includes splitting the wiring substrate by bending the wiring substrate along the groove in the wiring substrate and the thin region in the sealing resin.

6. The method for manufacturing a semiconductor device according to claim 3, wherein the step for dividing the wiring substrate into a plurality of chips includes splitting the wiring substrate by bending the wiring substrate along the perforated groove in the wiring substrate and the thin region in the sealing resin.

7. The method for manufacturing a semiconductor device according to claim 1, further comprising:
coupling the first semiconductor substrates to the wiring substrate using a wire,
between the step for fixing the plurality of first semiconductor substrates onto the wiring substrate and the step for covering the surface of the wiring substrate with the metal mold.

8. The method for manufacturing a semiconductor device according to claim 1, further comprising:
fixing a second semiconductor substrate on each of the plurality of first semiconductor substrates; and
coupling the second semiconductor substrate to the wiring substrate using a wire,
between the step for fixing the plurality of first semiconductor substrates onto the wiring substrate and the step for covering the surface of the wiring substrate with the metal mold.

9. The method for manufacturing a semiconductor device according to claim 1, further comprising:
fixing a plurality of second semiconductor substrates onto each of the plurality of semiconductor substrates, with the plurality of second semiconductor substrates laminated with each other; and
coupling at least one of the plurality of laminated second semiconductor substrates to the wiring substrate using a wire,
between the step for fixing the plurality of first semiconductor substrates onto the wiring substrate and the step for covering the surface of the wiring substrate with the metal mold.

10. A method for manufacturing a semiconductor device, comprising:
fixing each of a plurality of semiconductor substrates onto a surface of a wiring substrate in which a perforation is formed in advance;
wholly sealing the plurality of first semiconductor substrates with a sealing resin while forming a thin region in the sealing resin along the perforation; and
dividing the wiring substrate into a plurality of chips by splitting the wiring substrate and the sealing resin along the perforation in the wiring substrate and the thin region in the sealing resin.

11. The method for manufacturing a semiconductor device according to claim 1, wherein the perforation in the wiring substrate is formed by means of laser irradiation or etching.

12. The method for manufacturing a semiconductor device according to claim 1, wherein a thickness of the thin region in the sealing resin is ⅓ or less of a thickness of the sealing resin around the first semiconductor substrates.

13. A semiconductor device, comprising:
a semiconductor substrate;
a wiring substrate coupled to the semiconductor substrate, which is fixed on the wiring substrate; and
a sealing resin for sealing the semiconductor substrate on the wiring substrate,
wherein: the sealing resin is thinner on at least one side of the wiring substrate than other regions; and
the side of the wiring substrate is formed by splitting the wiring substrate along a perforation formed in the wiring substrate.

14. A semiconductor device, comprising:
a semiconductor substrate;
a wiring substrate coupled to the semiconductor substrate, which is fixed on the wiring substrate; and
a sealing resin for sealing the semiconductor substrate on the wiring substrate,
wherein: the sealing resin is thinner on at least one side of the wiring substrate than other regions; and
the side of the wiring substrate is formed by splitting the wiring substrate along a groove formed in the wiring substrate.

15. A semiconductor device, comprising:
a semiconductor substrate;
a wiring substrate coupled to the semiconductor substrate, which is fixed on the wiring substrate; and
a sealing resin for sealing the semiconductor substrate on the wiring substrate,
wherein: the sealing resin is thinner on at least one side of the wiring substrate than other regions; and
the side of the wiring substrate is formed by splitting the wiring substrate along a perforated groove formed in the wiring substrate.

16. A metal mold, comprising:
a protrusion on an inner surface along a perforation or a groove formed in a surface of a wiring substrate, onto which a semiconductor substrate is fixed,
wherein purposes of use include to seal the semiconductor substrate with resin and to cover a surface of the wiring substrate.
